(19) United States
(12) Patent Application Publication
(10) Pub. No.: US 2016/0340776 A1
(43) Pub. Date: Nov. 24, 2016

(54) ROLLER FOR SPREADING OF A FLEXIBLE SUBSTRATE, APPARATUS FOR PROCESSING A FLEXIBLE SUBSTRATE AND METHOD OF OPERATING THEREOF

(71) Applicants: Andreas Sauer, Großostheim (DE); Florian Ries, Westerngrund (DE); Thomas Deppisch, Aschaffenburg (DE); Applied Materials, Inc., Santa Clara, CA (US)

(72) Inventors: Andreas SAUER, Großostheim (DE); Florian RIES, Westerngrund (DE); Thomas DEPPISCH, Aschaffenburg (DE)

(21) Appl. No.: 15/112,800

(22) PCT Filed: Jan. 22, 2014
(86) PCT No.: PCT/EP2014/051260

§ 371 Date: Jul. 20, 2016

(51) Int. Cl. C23C 14/56; C23C 14/34; C23C 14/54; C23C 16/505; C23C 16/46; C23C 14/24; C23C 16/52

(52) U.S. Cl. CPC C23C 14/562; C23C 14/24; C23C 14/34; C23C 14/568; C23C 16/52; C23C 16/505; C23C 16/463; C23C 14/541

(57) ABSTRACT

A processing apparatus for processing a flexible substrate in a vacuum chamber is described. The processing apparatus includes a processing drum for processing the flexible substrate while being guided on the processing drum, a roller arrangement having one or more rollers configured to contact the flexible substrate along a portion of one or more circumferences of the one or more rollers before the flexible substrate is guided on the processing drum, wherein the combined length of contact along one or more portions of the one or more circumferences of the one or more rollers is 270 mm or above, and wherein an individual length of contact along each of the one or more portions of the one or more circumferences of the one or more rollers is 500 mm or below, and a temperature adjustment element adjusting the temperature of the one or more rollers.

### TECHNICAL FIELD OF THE INVENTION

Embodiments of the present invention relate to a vacuum processing apparatus with a roller. Embodiments of the present invention particularly relate to a vacuum processing apparatus with a roller arrangement for coating flexible substrates, specifically to guiding roller arrangements for guiding flexible substrates during a vacuum processing process. Embodiments of the present invention further relate to a method for operating a roller in a vacuum processing apparatus.

### BACKGROUND OF THE INVENTION

Processing of flexible substrates, such as plastic films or foils, is in high demand in the packaging industry, semiconductor industries and other industries. Processing may consist of coating of a flexible substrate with a desired material, such as a metal, in particular aluminum, semiconductor and dielectric materials, of etching and of other processing steps conducted on a substrate for the desired applications. Systems performing this task generally include a processing drum, e.g., a cylindrical roller, coupled to a system for transporting the substrate. Further roller devices may help to guide and direct the substrate to be coated in the processing chamber.

Generally, a sputter process, an evaporation process, for instance a thermal evaporation process, or a CVD process, for instance a plasma enhanced CVD process, can be utilized for depositing thin layers onto flexible substrates. Roll-to-Roll deposition systems are also experiencing a strong increase in demand in the display industry and the photovoltaic (PV) industry. For example, touch panel elements, flexible displays, and flexible PV modules result in an increasing demand for depositing suitable layers in Roll-to-Roll coaters, particularly with low manufacturing costs.

Flexible substrates can be processed with a plurality of processes, such as PVD, CVD, such as PECVD, etching, thermal processing or the like. Particularly for manufacturing more sophisticated electronics, optoelectronics or other devices, contacting of the surface, which is to be processed or has been processed needs to be avoided. Yet further, the requirements of the processing, e.g. deposition, show increasing demands with respect to uniformity, precision and the like, particularly for thin films. Thereby, the substrate needs to be transported and wound wrinkle-free.

Flexible substrates, which may also be called films, can easily get wrinkles or waves when winding the flexible substrate in a roll-to-roll coater. As one countermeasure, spreader rollers or so-called Nip-rollers can be provided to reduce wrinkles. However, temperature differences in the processing apparatus may still occur and the results thereof may not be fully compensated by the existing spreading devices. Such temperature differences may additionally lead to wrinkles or waves in the flexible substrate.

In view of the above, it is desirable to provide a processing apparatus including a roller and a method for operating a roller in a vacuum processing apparatus that overcome at least some of the above problems.

### SUMMARY OF THE INVENTION

In light of the above, a processing apparatus for processing a flexible substrate in a vacuum chamber and a method of processing a flexible substrate in a vacuum processing apparatus are provided. Further aspects, advantages, and features of the present invention are apparent from the dependent claims, the description, and the accompanying drawings.

According to one embodiment, a processing apparatus for processing a flexible substrate in a vacuum chamber is provided. The processing apparatus includes a processing drum for processing the flexible substrate while being guided on the processing drum, a roller arrangement having one or more rollers configured to contact the flexible substrate along a portion of one or more circumferences of the one or more rollers before the flexible substrate is guided on the processing drum, wherein the combined length of contact along one or more portions of the one or more circumferences of the one or more rollers is 270 mm or above, and wherein an individual length of contact along each of the one or more portions of the one or more circumferences of the one or more rollers is 500 mm or below, and one or more temperature adjustment elements adjusting the temperature of the one or more rollers.

According to another embodiment, a method of processing a flexible substrate in a vacuum processing apparatus is provided. The method includes guiding the substrate in a vacuum chamber using a roller in the vacuum chamber, wherein the guiding comprises a combined length of contact along one or more portions of the one or more circumferences of the one or more rollers of 270 mm or above, wherein an individual length of contact along each of the one or more portions of the one or more circumferences of the one or more rollers is 500 mm or below, and adjusting the temperature of the flexible substrate towards the temperature of a processing drum while the substrate is in contact with the roller.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1A shows a portion of a processing apparatus including the processing drum and a roller configured for temperature adjustment according to embodiments described herein;

FIGS. 1B and 1C show processing apparatuses including a processing drum and a roller configured for temperature adjustment according to embodiments described herein;

FIG. 2 shows a schematic view of a roller device and a heating device which can be utilized for embodiments described herein;

FIG. 3A shows a schematic partial view of a roller device and a heating device which can be utilized for embodiments described herein;

FIG. 3B shows a schematic partial view of a roller device and a heating device which can be utilized for embodiments described herein;

FIG. 4 shows a schematic view of a roller device and a heating device which can be utilized for embodiments described herein;

FIG. 5 shows a schematic view of a roller device and a cooling device which can be utilized for embodiments described herein; and

FIG. 6 shows a flowchart illustrating a method of temperature adjustment of the flexible substrate according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

Furthermore, in the following description, a roller or roller device may be understood as a device, which provides a surface, with which a substrate (or a part of a substrate) may be in contact during the presence of the substrate in a deposition arrangement (such as a deposition apparatus or deposition chamber). At least a part of the roller device may include a circular-like shape for contacting the substrate. In some embodiments, the roller device may have a substantially cylindrical shape. The substantially cylindrical shape may be formed about a straight longitudinal axis or may be formed about a bent longitudinal axis. According to some embodiments, the roller device as described herein may be adapted for being in contact with a flexible substrate. The roller device as referred to herein may be a guiding roller adapted to guide a substrate while the substrate is coated (or a portion of the substrate is coated) or while the substrate is present in a deposition apparatus; a spreader roller adapted for providing a defined tension for the substrate to be coated; a deflecting roller for deflecting the substrate according to a defined travelling path or the like.

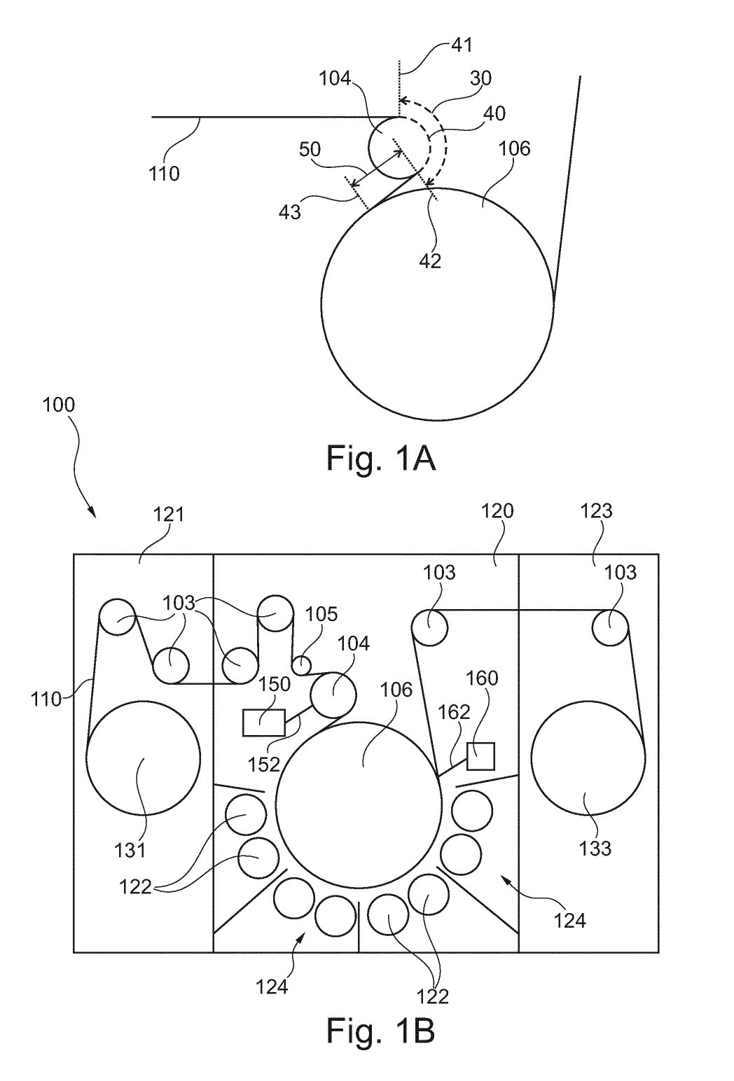

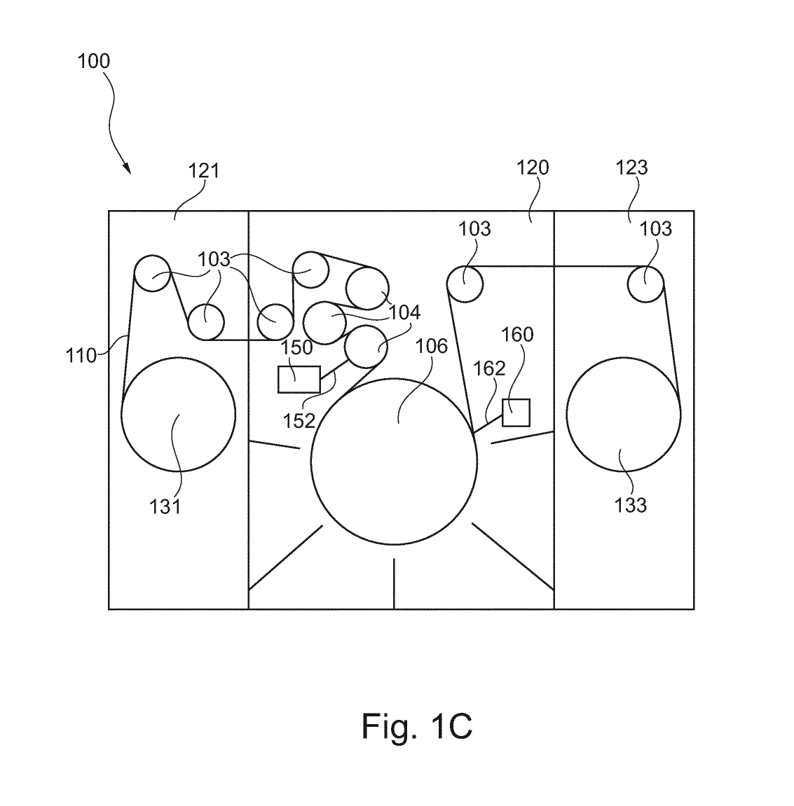

FIG. 1A shows processing drum 106 onto which a substrate 110 is guided, i.e. supported, during processing of the substrate. Typically, the substrate can be heated or cooled to a desired temperature for processing the flexible substrate. For example, a layer deposition on the substrate may require raising the temperature of the substrate to the desired deposition temperature. In order to raise the temperature of the substrate, the processing drum can include temperature adjustment means, for example a heating device to heat at least the surface of the processing drum 106. Accordingly, the flexible substrate is heated while being in contact with the surface of the processing drum 106.

According to some embodiments, which can be combined with other embodiments described herein, a substrate as described herein may include materials like PET, HC-PET, PE, PI, PU, TaC, one or more metals, paper, combinations thereof, and already coated substrates like Hard Coated PET (e.g. HC-PET, HC-TAC) and the like.

The flexible substrate, which may also be referred to as film, may get waves or wrinkles when it comes into contact with the processing drum, which may have a different temperature compared to the film temperature before heating of the film, i.e. the flexible substrate. For example, so-called heat waves, which may be caused by degassing of the substrate, may impede the smooth winding of the flexible substrate on the processing drum. Depending on the type of the flexible substrate or film, the change of temperature can result in an expansion of the flexible substrate or a shrinkage of the flexible substrate, both of which may further result in waves or wrinkles.

As shown in FIG. 1A, a roller 104 is provided according to embodiments described herein, which is configured to adjust the temperature of the flexible substrate 110 to the temperature of the processing drum 106 before the substrate gets in contact with the processing drum 106 at the processing drum contact position, which is illustrated by the dotted line 43. The flexible substrate 110 is heated or cooled by the roller having a temperature adjustment element, while the flexible substrate is in contact with the roller 104. The length 40 of the contact of the flexible substrate and the roller 104 is indicated by a dashed line. The length 40 is determined by the diameter (or radius) of the roller 104 and the wrapping angle 30 between the roller contact position, which is indicated by the dotted line 41, and the roller exit position, which is indicated by the dotted line 42.

According to embodiments described herein, the length 40 of the contact of the flexible substrate and the roller 104 is from 270 mm to 500, such as from 300 mm to 350 mm. The length of contact, i.e. the portion of the circumference of the roller 104, which is defined by the wrapping angle, is sufficiently long to heat the substrate 110 and is sufficiently short to allow for gliding or slipping of the flexible substrate on the surface of the roller 104. By gliding or slipping of the flexible substrate on the surface of the roller, waves or wrinkles can be reduced or avoided.

In order to allow for a sufficiently long length of contact, the roller 104 may have an increased diameter as compared to other rollers, such as a guiding roller, which may typically be utilized in a roll-to-roll coater. According to some embodiments, which can be combined with other embodiments described herein, the diameter of the roller 104 can be 180 mm or above. Yet, the diameter is typically significantly smaller than the diameter of the processing drum 106, for example below 300 mm.

Embodiments described herein provide the opportunity to balance the temperature of the flexible substrate, i.e. a film. Once the flexible substrate or film is e.g. preheated before a hot processing drum or coating drum, the heat waves can be eliminated or significantly reduced.

For example, a heated guide roller with a diameter of less than 200 mm can be used to heat, i.e. pre-heat, the flexible substrate or film. Since the bending of the film is much higher on such a roller compared to the coating drum (diameter, e.g. 1400 mm) no heat waves are generated on such a roller. According to some embodiments, which can be combined with other embodiments described herein, the wrapping angle is at least 90°, e.g. 160° to 200°.

According to embodiments described herein, the roller, for example roller 104 in FIG. 1A, can be set to the desired temperature to adjust the temperature of the flexible substrate to the temperature, which is required during processing while the substrate is guided on to the processing drum. Due to a pre-heating or pre-cooling, i.e. a temperature adjustment, the flexible substrate or a foil and, thus, finally the product, can be kept in shape. A wrinkling, unwanted shrinking or expanding on the processing drum can be reduced or avoided. The length of contact between the flexible substrate and the roller is sufficiently large to allow for temperature adjustment before the flexible substrate, i.e. a film or foil, is further guided to the processing drum. Further, the length of contact between the flexible substrate and the roller is sufficiently small to avoid disadvantageous behavior of the flexible substrate, which may for example occur on a processing drum having an even larger diameter.

According to yet further embodiments, which can be combined with other embodiments described herein, the distance 50 between the roller exit position, which is indicated by the dotted line 42, and the processing drum contact position, which is indicated by the dotted line 43, is 600 mm or below. Thereby, significant temperature changes after the flexible substrate lost contact to the roller, can be avoided and in adjustment of the temperature of the flexible substrate for contacting the processing drum can be more easily conducted.

FIG. 1B shows a processing apparatus 100 for a flexible substrate 110 according to embodiments described herein. The processing apparatus includes a vacuum chamber 120. A processing drum 106 or coating drum is provided in the vacuum chamber 120. One or more processing stations 124 are provided in the vacuum chamber 120 to process the substrate, while the substrate is guided on the processing drum. FIG. 1B exemplarily shows for processing stations 124 in the form of four deposition stations. Exemplarily, each of the processing stations 124 is shown by a pair of rotatable sputtering targets 122.

As further shown in FIG. 1B, a coating drum or a processing drum 106 has a rotation axis, which is provided in the apparatus. The processing drum has a curved outer surface for guiding the substrate along the curved outer surface. The substrate is thereby guided through a first vacuum processing region and, e.g. at least one second vacuum processing region. Even though it is often referred to herein to deposition stations being the processing stations, also other processing stations, like etch stations, heating stations, etc. can be provided along the curved surface of the processing drum 106. Accordingly, the apparatuses described herein, and having compartments for various deposition sources allow for a modular combination of several CVD, PECVD and/or PVD processes in a single deposition apparatus, e.g. a R2R coater.

According to some embodiments, the processing stations can be modularly equipped with different processing tools. The modular concept, wherein all kinds of deposition sources can be used in a deposition apparatus according to embodiments described herein, helps to bring down costs for the deposition of complex layer stacks that have to be deposited applying different deposition technologies or intricate combinations of process parameters.

Generally, according to different embodiments, which can be combined with other embodiments described herein, the plasma deposition source can be adapted for depositing a thin film on a flexible substrate, e.g., a web or a foil, a glass substrate or silicon substrate. Typically, the plasma deposition source can be adapted for and can be used for depositing a thin film on a flexible substrate, e.g., to form a flexible TFT, a touch screen device component, or a flexible PV module.

In accordance with embodiments described herein, a plasma deposition source can be provided as a PECVD (plasma-enhanced chemical vapor deposition) source having a multi-region electrode device including two, three or even more RF (radio frequency) electrodes arranged opposite to a moving web. According to embodiments, multi region plasma deposition sources can also be provided for MF (middle frequency) deposition. According to yet further embodiments, which can be combined with other embodiments described herein, one or more deposition sources, which are provided in the a deposition apparatus as described herein, can be a microwave source and/or can be a sputter source, e.g. a sputter target, particularly a rotary sputter target as shown in FIG. 1B. For example, for a microwave source, a plasma is excited and maintained plasma by microwave radiation and the source is configured to excite and/or maintain the plasma with microwave radiation.

As shown in FIG. 1B, the substrate 110 is guided from a unwinding roller 131 to the processing drum 106 and is wound on to a rewinding roller 133 of the processing of flexible substrate. In order to guide the flexible substrate 110 through the processing apparatus 100, a plurality of rollers 103 can be provided. Thereby, the rollers can provide at least one functionality selected from the group consisting of: guiding the flexible substrate, tensioning the flexible substrate, spreading the flexible substrate, charging the flexible substrate, de-charging the flexible substrate, and heating or cooling the flexible substrate. FIG. 1B shows a roller 104 similar to the roller 104 shown in FIG. 1A, wherein the diameter is configured to provide a desired length of contact between the flexible substrate 110 and the roller 104. According to some embodiments, which can be combined with other embodiments described herein, additionally a wrapping angle adjustment roller 105 can be provided in order to provide or adjust a wrapping angle of the flexible substrate around the roller 104 as described herein. For example, the arrangement of the wrapping angle adjustment roller 105, the temperature adjustment roller 104, and the processing drum 106 can be such that the roller 104 is provided between the wrapping angle adjustment roller 105 and the processing drum 106.

According to some embodiments, which can be combined with other embodiments described herein, the processing drum 106 can be heated or cooled to a desired processing temperature. The controller 160 is connected to a heating or cooling device within the processing drum 106 by a connection 162. According to typical embodiments, the processing drum 106 can be heated for deposition purposes, and may for example be cooled during an etch process. A further controller 150 is connected via connection 152 to roller 104 in order to adjust the temperature of the roller 104 with a temperature adjustment means provided therein. Accordingly, the temperature of the flexible substrate 110 can be adjusted by the temperature adjustment roller 104 before the flexible substrate comes into contact with the processing drum 106. According to embodiments described herein, the length of contact between the flexible substrate and the roller 104 is configured to be sufficiently large for temperature adjustment of the flexible substrate and is sufficiently small to avoid wrinkles and/or waves of the flexible substrate.

According to yet further embodiments, which can be combined with other embodiments described herein, the wrapping angle is at least 150°, for example 160° to 200°. Since the bending of the flexible substrate is higher on the roller 104 as compared to the bending of the substrate on the processing drum 106, heat waves, which may occur due to gassing of flexible substrate, can be reduced or avoided.

FIG. 1C shows a further processing apparatus 100 for a flexible substrate 110 according to embodiments described herein. The processing apparatus includes a vacuum chamber 120. A processing drum 106 or coating drum is provided in the vacuum chamber 120. According to some embodiments, the processing stations can be modularly equipped with different processing tools, for example as described with respect to FIG. 1B. However, the processing drum may also be used for outgassing of the flexible substrate. This is exemplarily shown in FIG. 1C, where the processing drum itself is provided as the processing drum, e.g. for outgassing of the flexible substrate. The flexible substrate can be outgassed by heating the processing drum to a temperature of 100° C. or above. Outgassing of the processing drum without pre-heating may result in waves of the substrate on the drum due to the gas being trapped between the drum and the flexible substrate. In light of the large diameter of the processing drum, i.e. a large contact length along the circumference of the drum, the waves cannot be easily avoided and prevent sufficient substrate handling.

As shown in FIG. 1C, the substrate 110 is guided from a unwinding roller 131 to the processing drum 106 and is wound on to a rewinding roller 133 of the processing of flexible substrate. In order to guide the flexible substrate 110 through the processing apparatus 100, a plurality of rollers 103 can be provided. Thereby, the rollers can provide at least one functionality selected from the group consisting of: guiding the flexible substrate, tensioning the flexible substrate, spreading the flexible substrate, charging the flexible substrate, de-charging the flexible substrate, and heating or cooling the flexible substrate. FIG. 1C shows a roller arrangement having more than one roller 104 similar to the roller 104 shown in FIG. 1A, wherein the diameter of the rollers, the number of rollers, and/or the wrapping angles of the rollers are configured to provide a desired length of contact between the flexible substrate 110 and the roller arrangement. The rollers of the roller arrangement have temperature adjustment means, e.g. heating devices shown in FIG. 1C.

According to some embodiments, which can be combined with other embodiments described herein, the processing drum 106 can be heated or cooled to a desired processing temperature. The temperature of the flexible substrate 110 can be adjusted by the temperature adjustment roller arrangement before the flexible substrate comes into contact with the processing drum 106. According to embodiments described herein, the combined length of contact between the flexible substrate and the roller arrangement is configured to be sufficiently large for temperature adjustment of the flexible substrate and the individual length of contact between the flexible substrate and each roller of the roller arrangement individually is sufficiently small to avoid wrinkles and/or waves of the flexible substrate.

According to one embodiment, which can be combined with other embodiments described herein, the processing can be an outgassing of the flexible substrate. As shown in FIG. 1C, the processing drum 106 can be heated for outgassing of the flexible substrate. For example, the flexible substrate can be heated to 100° C. or above, for example 130° C. to 170° C. Depending on the material of the flexible substrates, even higher temperature may further be possible. In order to adjust the temperature of the flexible substrate before the flexible substrate comes to contact with the processing drum, a roller arrangement having one or more rollers configured for heating the flexible substrate is provided. The one or more rollers of the roller arrangement have temperature adjustment means, for example heating devices 222 heat the substrate towards the temperature of the processing drum. According to alternative embodiments, the temperature of the flexible substrate can be adjusted to be slightly below the temperature of the processing drum, for example less than 20° C. below the processing drum temperature (under-regulation), the temperature of the flexible substrate can be adjusted to be slightly above the temperature of the processing drum, for example less than 20° C. above the processing drum temperature (over-regulation), or the temperature of the flexible substrate can be adjusted to be about the same temperature as the processing drum.

In the case of a cooled processing drum, an adjustment control having an under-regulation can adjust the temperature to be slightly above the temperature of the processing drum and just been control having an over-regulation can adjust the temperature to be slightly below the temperature of the processing drum.

The desired length of contact for adjusting the temperature of the flexible substrate to the temperature of the processing drum or, according to some embodiments, which can be combined with other embodiments described herein, to temperature range of +−20° C. around the temperature of the processing drum may also depend on the transportation speed of the flexible substrate within the processing apparatus. Yet, embodiments described herein provide a length of contact of the flexible substrate with a roller having a temperature adjustment element or a combined length of contact of the flexible substrate with a roller arrangement having two a more rollers with temperature adjustment elements based upon a desired transportation speed. Accordingly, embodiments described herein provide an apparatus capable of processing the flexible substrate at sufficiently high speed. According to different embodiments, in the event of two or more rollers for temperature adjustment, each roller can have an individual temperature adjustment element, or some (or all) of the rollers can share a common temperature adjustment element.

Embodiments described herein, partly referred to a roller arrangement having one or more rollers, e.g. rollers having a temperature adjustment element. Thereby, in the event one roller having a temperature adjustment element is provided, the roller arrangement includes one roller and the combined length of contact between the flexible substrate and the roller relates to one portion of one circumference of the one roller. The combined length of contact, i.e. the one single length of contact has a lower limit and an upper limit as described herein. For roller arrangements having two or more rollers, the combined length of contact between the flexible substrate and the roller arrangement is the sum of the portions of the circumference is of the two or more rollers. The combined length of contact has a lower limit. Additionally, each of the rollers of the roller arrangement individually has an upper limit as described herein.

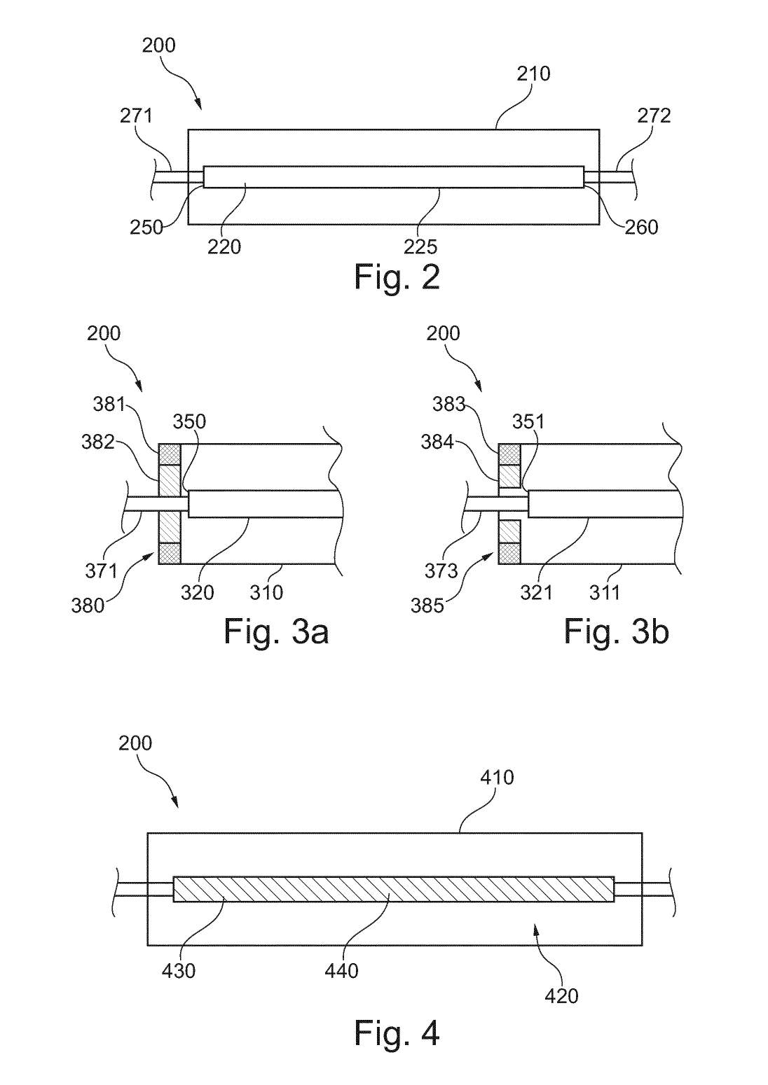

In the following, various options of temperature adjustment of a roller, which is used similar to the rollers 104 shown in FIGS. 1A and 1B, will be described. FIG. 2 shows an embodiment of a roller device 200, which may be used in a processing apparatus according to embodiments described herein. For instance, the roller device 200 as shown in FIG. 2 may be used in the deposition apparatus 100 as exemplarily shown in FIG. 1B. The roller device 200 may include a surface 210, which is adapted to be in contact with the flexible substrate to be processed, for example on to which material is to be deposited.

Although the figures only show straight roller devices, the roller devices shown in the figures may also be spreader rollers, such as spreader rollers having a curved surface along the length direction of the roller. The curved surface of a spreader roller may have a tensioning effect in the width direction of the substrate.

Within the roller device 200, an electrical heating device 220 is provided. The electrical heating device 220 may be adapted to be operated in a vacuum, such as a vacuum deposition chamber. For instance, the electrical heating device may be adapted to the pressure fluctuation occurring while the deposition chamber is pumped down to vacuum conditions. This may be achieved by choosing a suitable design and construction of the heating device, suitable materials for the heating device, or suitable isolating materials for the heating device as will be explained in detail below.

An electrical heating device as described herein should be understood as a heating device for heating the roller device, in which it is arranged. According to some embodiments, the electrical heating device may be a heating device heating a surface electromagnetically. For instance, the heating device may be an irradiation heating device, such as an infrared heating device, an induction heating device or the like. According to some embodiments, the electrical heating device is a contactless heating device. The contactless heating device may be able to bring the roller device, or a surface of the roller device, to a defined temperature without making contact with it, especially without making contact with it for the purpose of heating. It should be understood that the heating device may nevertheless have defined contact areas with the roller, e.g. for being supported in the roller device.

According to embodiments described herein, a power density, that is a heating power per roll length, of at least 1 kW/m el. Power of the heating device, i.e. electrical power provided to the heating device or above can be provided by the heating device to adjust the temperature of the substrate.

In some embodiments, the roller device may have a certain heated length that is to be heated by the heating device and the heating device has no contact with the roller device over the heated length. According to some embodiments, the heating device may provide two ends and is adapted for being supported, held or fixed at both ends. In one embodiment, the heating device may have a substantially cylindrical form, wherein the two ends of the heating device are the two ends of the longitudinal axis of the substantially cylindrical heating device or wherein the two ends of the heating device include the two front sides of the substantially cylindrical heating device.

According to some embodiments described herein, the heating device is adapted to provide the outer surface of the heating device substantially at the same electrical potential as the roller device during vacuum deposition. In FIG. 2, the outer surface of the heating device is denoted with reference sign 225. According to some embodiments, the outer surface of the heating device is the surface of the heating device facing the roller device. In one embodiment, the outer surface 225 of the heating device 220 and the roller device, specifically the surface 210 of the roller device 200, may both be at ground potential. In one embodiment, which may be combined with other embodiments described herein, the heating device and the roller device are adapted to hold the surface of the heating device facing the roller device substantially on the same potential as the roller device over the heating length during vacuum deposition.

The term “substantially” as used herein may mean that there may be a certain deviation from the characteristic denoted with “substantially.” For instance, the term “substantially at the same potential” refers to a situation, where the potential of the two elements having substantially the same potential may have certain deviations from the exact same potential, such as a deviation of about 1% to 15% of the electrical potential of one of the elements, or having a potential difference of 20 V or below. In one embodiment, having or being on “substantially the same potential” may be understood in that the difference of the potential between two elements having substantially the same potential is small enough so that there is no voltage discharge risk between the two elements especially under vacuum conditions.

In the processing apparatus according to embodiments described herein, the same vacuum may be present in the vacuum chamber and within the roller device. According to some embodiments, the “same vacuum” may mean that the deviation of the vacuum in the vacuum chamber outside the roller device and within the roller device is within a variation of the vacuum condition which may typically be present in a vacuum chamber, e.g. a vacuum chamber having a defined size. For instance, the “same vacuum” being present within the roller device and outside the roller device in the vacuum chamber may mean that the roller device with the heating device in it is not isolated with respect to the vacuum chamber. In the processing apparatus, one vacuum generating arrangement, i.e. a single arrangement, e.g. one vacuum pump, may be used for the vacuum in the vacuum chamber and the inside of the roller device.

In FIG. 2, the first end 250 and the second end 260 of the heating device 220 can be seen; especially the first end 250 and the second end 260 can be seen as being located at the front sides of the substantially cylindrical shape of the heating device. Generally, the heating device, in embodiments described herein, is held at the first end 250 and at the second end 260. According to some embodiments, the first end 250 of the heating device 220 is held by at least one holding device, e.g. by a first holding device 271, and the second end 260 of the heating device 220 is held by a second holding device 272.

For instance, the heating device may be held by the at least one holding device extending along the length of the heating device in the roller device. In one example, the holding device, which provides the holding function for the first and the second end of the heating device, may provide a support of the heating device in the vacuum chamber or in the roller device.

According to some embodiments, the holding device or the holding devices may be supported in the vacuum chamber. For instance, the deposition apparatus may be adapted for fixing the holding devices holding the ends of the heating device within the roller device. In one embodiment, the processing apparatus includes at each side of the heating device (with respect to the longitudinal axis) a support for fixing the holding devices. According to further embodiments, the holding devices are fixed outside the vacuum chamber of the processing apparatus. In some embodiments, the roller device may also be supported by the holding devices, or the holding devices may be supported in the roller device, as explained in more detail with respect to FIGS. 3A and 3B. In some embodiments, which may be combined with other embodiments described herein, the holding device, or the holding devices, may include one bearing for each end of the heating device to be held.

According to some embodiments, the holding device or the holding devices may include one or more receptions for holding and guiding power supply lines for the power supply of the heating device. In one example, the holding device allows for connecting the power lines to the heating device, when the holding device is connected to the heating device. In one embodiment, two holding devices are provided for being connected at each side of the heating device.

According to some embodiments described herein, the accuracy of the roller device arrangement in the vacuum chamber may be increased. For instance, by supporting the heating device and the roller device at both ends (and, in some embodiments, independently from one another), the roller device and the heating device may be held stable during processing, especially irrespective of the substrate weight or the duration of the process. In some embodiments, the accuracy of the position of a roller device being held at both ends may typically be in a range of about 1/100 mm to about ⅕ mm per meter length of the roller device, more typically between about 1/100 mm and about 1/10 mm per meter length of the roller device, and even more typically between about 1/100 mm and about 1/50 mm per meter length of the roller device. For instance, the position of the ends of the roller device deviates from the desired position by less than 1/10 mm per meter length. According to some embodiments, a high accuracy of the roller device position may be desirable for ensuring a reliable operation of the deposition apparatus. Further, as explained above, holding the heating device at both ends allows for an “open” design of the roller device. An “open” design of the roller device may include a design, which is not vacuum-tight. Also, supplying power to the heating device is facilitated by the open design of the roller device and/or the holding of both ends of the heating device.

FIG. 3A shows a partial view of a roller device 200, which may be used in a deposition apparatus according to embodiments described herein. The roller device 200 includes a surface 310 to be in contact with the substrate to be coated. A heating device 320 can partially be seen in FIG. 3A. In the embodiment shown in FIG. 3A, the roller device 200 is rotatably connected to the holding device. For instance, the roller device 200 may rotatably be connected to the holding device by a bearing arrangement 380. The bearing arrangement 380 may allow the roller device to rotate on the holding device 371. In some embodiments, the bearing arrangement 380 includes a bearing 381 and a supporting element 382. The supporting element 382 may be provided for supporting the roller device 300, for instance on the holding device or in the vacuum chamber. When connecting the roller device rotatably on the holding device holding the heating device inside the roller device, the roller device may be rotated about the heating device. Therefore, the surface of the roller device is uniformly heated by passing the heating device whilst rotating.

FIG. 3B shows an embodiment of a roller device 200 including a heating device 321. The roller device 200 is shown having a surface 311 to be in contact with the substrate during processing. As can be seen in the example of FIG. 3B, the heating device 321 is held by holding device 373. The roller device 301 may rotatably be provided by a bearing arrangement 385. In the embodiment shown in FIG. 3B, the bearing arrangement 385 includes a bearing 383, which allows the roller device 200 to rotate. The supporting element 384 supports the bearing 383 and may be supported by the processing chamber, which the roller device 200 is arranged in. In some embodiments, the supporting element 384 may be a part of the deposition chamber. In the embodiment shown in FIG. 3B, there is no connection between the roller device 200 and the heating device 321. According to some embodiments, the roller device rotates independently from the heating device, in particular, without being connected to the heating device or vice versa.

According to some embodiments, which may be combined with other embodiments described herein, the heating device and the roller device may separately be supported. For instance, the heating device and the roller device may have separate support systems for holding the heating device and the roller device. In one example, the heating device may be supported in the vacuum chamber by one holding system and the roller device may be supported in the vacuum chamber by a holding system different from the holding system of the heating device, in particular, the heating device and the roller device may substantially have no connection to each other, or no structural connection to each other, or have no contact with each other.

FIG. 4 shows a roller device 200 according to embodiments, which may be combined with other embodiments described herein. The roller device 200 includes a surface 410 to be in contact with the substrate to be coated during the deposition process. Further, a heating device 420 is shown in FIG. 4. According to some embodiments, the heating device 420 includes a support 430 and a heating element 440, especially a heating tube. In the embodiment shown in FIG. 4, the heating element 440 is shown wound around the support 440.

According to some embodiments, which can be combined with other embodiments described herein, a heating device of the roller can be adapted to provide an outer surface of the heating device substantially at the same electrical potential as the roller during vacuum processing. In particular, the electrical potential of the outer surface of the heating device may deviate from the electrical potential of the roller device by less than 15% of the electrical potential of the roller or by less than 50 V.

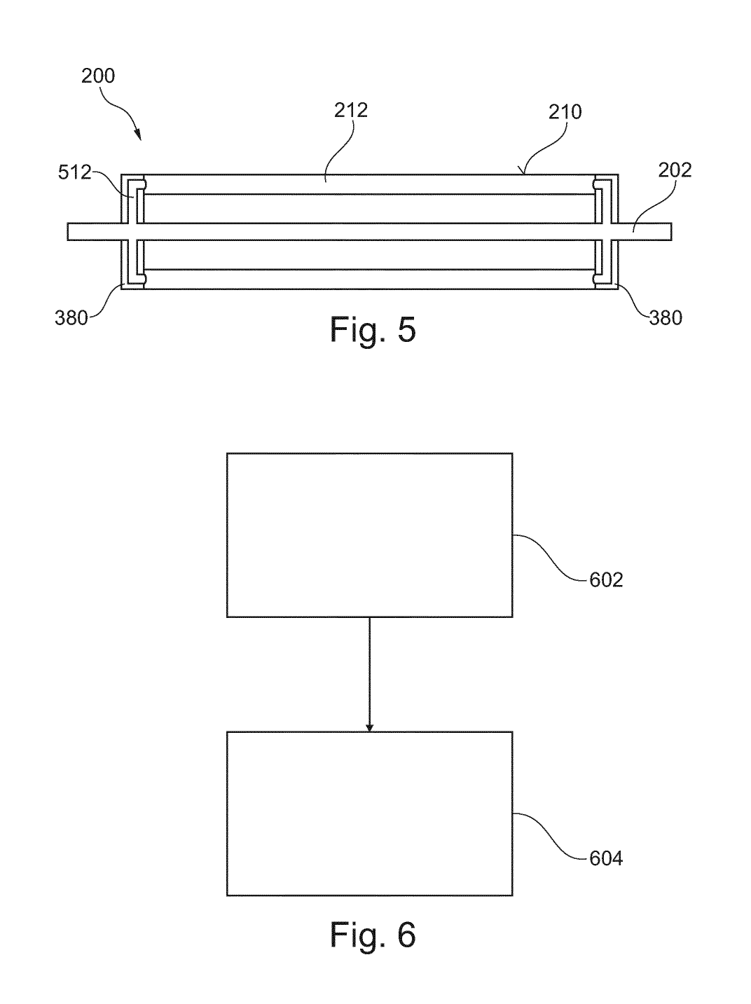

FIG. 5 shows a further roller 200, wherein a temperature adjustment element is provided in the form of the cooling device and/or heating device. The roller 200 has a substantially cylindrical form with an outer surface 210. The outer surface 210 is configured to be in contact with the flexible substrate. The roller can rotate around the axis 202. According to some embodiments, a bearing 380 can be provided to rotate a portion of the roller 200 around the axis 202. According to some embodiments, which can be combined with other embodiments described herein, a hollow space 212 can be provided. The hollow space 212 is configured to have the cooling fluid (or heating fluid) provided and/or circulated therein. Accordingly, the temperature of the outer surface 210 can be adjusted by the fluid.

According to some embodiments, which can be combined with other embodiments described herein, the fluid can be a gas, for example air, argon, nitrogen or the like, or the fluid can be a liquid, for example water, oil, or another liquid with a sufficiently large heat capacity. The cooling fluid (or heating fluid) can be provided in the hollow space 212 by ducts or channels 512, which may be connected to a duct or channel in the axis 202. An appropriate means for providing fluid in the hollow space of a rotating device, such as the roller 200, can be provided by appropriate means in the bearing 380. In order to avoid a fluid connection for a rotating device other cooling devices, such as thermoelectric cooling devices using the Peltier effect may also be utilized.

FIGS. 2 to 4 show a temperature adjustment element for a roller 200 in the form of a heating device. According to yet further embodiments, which can be combined with other embodiments described herein, the temperature adjustment element of the roller 200 shown in FIG. 5 can also be used as a heating device, wherein the hollow space 212 includes a heating fluid, i.e. one of the above-mentioned gases or liquids, which are heated to a temperature above the temperature of the roller. Accordingly, even though the rollers 200, which are described with respect to FIGS. 2, 3A and 3B, and FIG. 4, can advantageously be used in a vacuum chamber, other heating devices, such as the temperature adjustment element shown in FIG. 5, can be used for heating the roller.

According to yet further embodiments, which can be combined with other embodiments described herein, a heating device and a cooling device may also be provided together for a roller, which can be utilized in embodiments described herein. For example, a cooling device can be provided as described with respect to FIG. 5, and the heating device can be provided as described with respect to FIGS. 2 to 4. Yet further, the roller 200 as described with respect to FIG. 5 can be utilized for temperature adjustment in the form of heating and/or in the form of cooling.

FIG. 6 shows a flowchart illustrating a method of processing a flexible substrate in a vacuum processing apparatus according to embodiments described herein. The substrate is guided over a roller or one or more rollers in step 602, wherein the guiding comprises a combined length (40) of contact along the portion of the circumference of the roller is of 270 mm or above. In step 604 the temperature of the flexible substrate is adjusted such that the temperature gradient between the flexible substrate in the processing drum is reduced while the substrate is in contact with the one or more rollers. In the event of one roller, the length of contact of the flexible substrate with the one roller is 500 mm or below. In the event of two or more rollers, each lengths of contact for each of the rollers is 500 mm or below.

Embodiments described herein, provide an improved processing apparatus for a flexible substrate, such as a web-coater or roll-to-roll coater, wherein wrinkles or waves in the flexible substrate on the processing drum can be reduced or avoided. The pre-treatment of the flexible substrate in the form of heating or cooling is provided before the substrate gets in contact with the processing drum. Thereby, a temperature adjustment and/or degassing of the substrate, which may result in waves on the processing drum, can be provided. According to embodiments described herein, the length of the portion of the circumference of the roller having the temperature adjustment element, which is in contact with the flexible substrate hearing guiding thereof, is improved with respect to the heat adjustment capability, the capability to slide on the roller, and/or the wrapping angle. An improvement with respect to the wrapping angle can reduce or avoid waves, which may occur due to degassing of the flexible substrate.

While the foregoing is directed to embodiments of the invention, other and further embodiments of the invention may be devised without departing from the basic scope thereof, and the scope thereof is determined by the claims that follow.

1. A processing apparatus for processing a flexible substrate in a vacuum chamber, comprising:
a processing drum for processing the flexible substrate while being guided on the processing drum;
a roller arrangement having one or more rollers configured to contact the flexible substrate along a portion of one or more circumferences of the one or more rollers before the flexible substrate is guided on the processing drum, wherein the combined length of contact along one or more portions of the one or more circumferences of the one or more rollers is 270 mm or above, and wherein an individual length of contact along each of the one or more portions of the one or more circumferences of the one or more rollers is 500 mm or below; and
one or more temperature adjustment elements adjusting the temperature of the one or more rollers.

2. The processing apparatus according to claim 1, wherein the temperature adjustment element comprises a heating device.

3. The processing apparatus according to claim 2, wherein the heating device comprises a first end and a second end, and wherein the heating device is held at the first end and at the second end.

4. The processing apparatus according to claim 1, wherein the temperature adjustment element comprises a cooling device.

5. The processing apparatus according to claim 1, wherein the length of contact along the one or more portions of the one or more circumferences of the one or more rollers is 350 mm or above.

6. The processing apparatus according to claim 1, wherein a first roller of the one or more rollers is configured to contact the flexible substrate along the first portion of the first circumference of the first roller directly before the flexible substrate is guided on the processing drum.

7. The processing apparatus according to claim 1, wherein free-span distance of the flexible substrate from the first roller to the processing drum is from 50 mm to 600 mm.

8. The processing apparatus according to claim 1, wherein the diameter of the first roller is 180 mm or above.

9. The processing apparatus according to claim 1, wherein the diameter of the first roller is 300 mm or below.

10. The processing apparatus according to claim 1, wherein the one or more rollers are passively driven.

11. The processing apparatus according to claim 1, wherein the processing apparatus further comprises a vacuum generating arrangement for providing the same vacuum condition in the vacuum chamber outside the one or more rollers and within the one or more rollers.

12. A method of processing a flexible substrate in a vacuum processing apparatus, comprising:
guiding the flexible substrate in a vacuum chamber using roller arrangement having one or more rollers in the vacuum chamber, wherein the guiding comprises a combined length of contact along one or more portions of the one or more circumferences of the one or more rollers of 270 mm or above, wherein an individual length of contact along each of the one or more portions of the one or more circumferences of the one or more rollers is 500 mm or below; and
adjusting the temperature of the flexible substrate towards the temperature of a processing drum while the substrate is in contact with each of the one or more rollers.

13. The method according to claim 12, wherein the adjusting the temperature comprises heating of the flexible substrate or wherein the adjusting the temperature comprises cooling of the substrate.

14. A method according to claim 12, wherein the temperature of the flexible substrate is adjusted to be below the temperature of the processing drum by 20° or less or wherein the temperature of the flexible substrate is adjusted to be above the temperature of the processing drum by 20° C. or less.

15. The method according to claim 12, further comprising:
heating the processing drum to a temperature of 100° C. or above; and
outgassing the flexible substrate while being guided on the processing drum.

16. The processing apparatus according to claim 2, wherein the heating device comprises a first end and a second end, and wherein the heating device is fixed at a first end and at a second end in the vacuum chamber.

17. The processing apparatus according to claim 5, wherein the length of contact along the one or more portions of the one or more circumferences of the one or more rollers is 350 mm or above.

18. The processing apparatus according to claim 12, wherein the one or more rollers are driven by the flexible substrate.
